(19) United States
(12) Patent Application Publication
(10) Pub. No.: US 2024/0376013 A1
(43) Pub. Date: Nov. 14, 2024

(54) CERAMIC

(71) Applicant: Murata Manufacturing Co., Ltd., Nagaokakyo-shi (JP)

(72) Inventor: Sakyo HIROSE, Nagaokakyo-shi (JP)

(21) Appl. No.: 18/780,740

(22) Filed: Jul. 23, 2024

Related U.S. Application Data
(63) Continuation of application No. PCT/JP2023/012593, filed on Mar. 28, 2023.

(30) Foreign Application Priority Data
Mar. 31, 2022 (JP) 2022-059401

(51) Int. Cl. C04B 35/497; H10N 15/10

(52) U.S. Cl. CPC C04B 35/497; H10N 15/15; C04B 2235/3206; C04B 2235/3224; C04B 2235/3251; C04B 2235/3258; C04B 2235/3296; C04B 2235/768; C04B 2235/9607

(57) ABSTRACT

A ceramic represented by: (1−m)PbSc_{0.5-x}Ta_{0.5+x}O₃−mPbMg_{0.5-y}W_{0.5+y}O₃, wherein, 0.60≤m≤0.95; x, y≤0.1 and 0≤x+y≤0.13 when 0≤x, y; −0.1≤x≤0 and 0≤y≤0.1 when 0>x and 0≤y; −0.1≤x, y and −0.13≤x+y<0 when 0≥x and 0>y; and 0<x≤0.1 and −0.1≤y<0 when 0<x and 0>y.

### CROSS REFERENCE TO RELATED APPLICATIONS

The present application is a continuation of International application No. PCT/JP2023/012593, filed Mar. 28, 2023, which claims priority to Japanese Patent Application No. 2022-059401, filed Mar. 31, 2022, the entire contents of each of which are incorporated herein by reference.

### TECHNICAL FIELD

The present disclosure relates to a ceramic.

### BACKGROUND ART

In recent years, as a cooling element, a new solid cooling element and a new cooling system using an electrocaloric effect have attracted attention, and research and development thereof have been actively conducted. Compared with an existing cooling system using a refrigerant which is a greenhouse gas, there are advantages of high efficiency and low power consumption without requiring a refrigerant, and there is also an advantage of being quiet because no compressor is used. In order to obtain an excellent electrocaloric effect, a material that has a transition temperature in a desired temperature range and enables application of a large electric field is required. As such a material, PbSc_{0.5}Ta_{0.5}O₃ (hereinafter, a ceramic containing Pb, Sc, and Ta is also referred to as “PST”) (Patent Document 1, Non-Patent Documents 1 and 2) and PbMg_{0.5}W_{0.5}O₃ (hereinafter, a ceramic containing Pb, Mg, and W is also referred to as “PMW”) are known as promising materials. Non-Patent Document 3 reports that PbMg_{0.5}W_{0.5}O₃ exhibits large positive and negative electrocaloric effects.
Patent Document 1: WO 2021/131142
Non-Patent Document 1: Nature volume 575, pages 468 to 472 (2019)
Non-Patent Document 2: Ferroelectrics, 184, 239 (1996)
Non-Patent Document 3: Adv. Funct. Mater. 31, 2101176 (2021).

### SUMMARY OF THE DISCLOSURE

The PMW is an antiferroelectric and has a feature of being transferred to a ferroelectric by applying a voltage equal to or higher than a threshold voltage. The electrocaloric effect of the PMW is very small at a voltage equal to or lower than this threshold voltage, and when the voltage exceeds the threshold voltage, the PMW exhibits an electrocaloric effect according to the magnitude of the applied voltage. That is, when the PMW is used as a solid cooling element, it is necessary to apply a large voltage exceeding the threshold voltage of the PMW, and thus the electric field intensity required for exhibiting the electrocaloric effect also increases.

An object of the present disclosure is to provide a ceramic that exhibits a larger electrocaloric effect at a lower electric field than before. More specifically, an object of the present disclosure is to provide a ceramic that exhibits a larger electrocaloric effect at a lower electric field than that of a conventional PMW.

The present disclosure relates to a ceramic represented by Formula (1):

(1−m)PbSc_{0.5-x}Ta_{0.5+x}O₃−mPbMg_{0.5-y}W_{0.5+y}O₃ (1)

wherein
0.60≤m≤0.95,
x, y≤0.1 and 0≤x+y≤0.13 when 0≤x, y,
−0.1≤x<0 and 0≤y≤0.1 when 0>x and 0≤y,
−0.1≤x, y and −0.13≤x+y<0 when 0≥x and 0>y, and
0<x≤0.1 and −0.1≤y<0 when 0<x and 0>y.

The present disclosure includes the following aspects.

[1] A ceramic represented by Formula (1):

(1−m)PbSc_{0.5-x}Ta_{0.5+x}O₃−mPbMg_{0.5-y}W_{0.5+y}O₃ (1)

wherein
0.60≤m≤0.95,
when 0≤x, y, x, y≤0.1 and 0≤x+y≤0.13 when 0≤x, y,
when 0>x and 0≤y, −0.1≤x<0 and 0≤y≤0.1 when 0>x and 0≤y,
−0.1≤x, y and −0.13≤x+y<0 when 0≥x and 0>y, and
when 0<x and 0>y, 0<x≤0.1 and −0.1≤y<0 when 0<x and 0>y.

[2] The ceramic according to [1], wherein
0≤x+y≤0.1 when 0≤x, y, and
−0.1≤x+y<0 when 0≥x and 0>y.

[3] The ceramic according to [1] or [2], wherein x is 0 and y is 0.

[4] The ceramic according to any one of [1] to [3], wherein 0.6≤m≤0.9.

[5] The ceramic according to any one of [1] to [4], wherein a crystal structure of the ceramic has a perovskite structure.

[6] An electrocaloric effect element, wherein a noble metal electrode and the ceramic according to any one of [1] to [5] are alternately stacked.

[7] The electrocaloric effect element according to [6], wherein the noble metal electrode comprises Pt.

[8] An electronic component including the electrocaloric effect element according to [6] or [7].

[9] An electronic device including the electrocaloric effect element according to [6] or [7] or the electronic component according to [8].

According to the present disclosure, it is possible to provide a ceramic that exhibits a large electrocaloric effect at a low electric field. More specifically, it is possible to provide a ceramic that exhibits a larger electrocaloric effect at a lower electric field than a conventional PMW.

### BRIEF EXPLANATION OF THE DRAWINGS

FIG. 1 shows an electric polarization-electric field intensity curve of PMW at 15° C.

FIG. 2 shows an electric polarization-electric field intensity curve of a sample within the scope of the present disclosure at −18° C.

FIG. 3 is a schematic sectional view of an electrocaloric effect element according to an embodiment of the present disclosure.

FIG. 4 shows diagrams for explaining a measurement sequence of an electrocaloric effect.

FIG. 5 shows an electric polarization-electric field intensity curve of a PMW of sample No. 1 at 15° C.

FIG. 6 shows a relationship between an electrocaloric effect and an electric field intensity of a PMW of sample No. 1 at 15° C.

FIG. 7 shows a relationship between an electrocaloric effect and a temperature at an electric field intensity of 20 MV/m for the PMW of sample No. 1.

FIG. 8 shows a relationship between an electrocaloric effect and a temperature at an electric field intensity of 15 MV/m for a PST of sample No. 2.

FIG. 9 shows a relationship between an electrocaloric effect and a temperature at an electric field intensity of 15 MV/m for the PST of sample No. 2 and a sample of sample No. 6.

FIG. 10 is a graph showing results of a characteristic test for compositions of various x and y.

### DESCRIPTION OF THE PREFERRED EMBODIMENTS

Hereinafter, a ceramic of the present disclosure and an electrocaloric effect element using the ceramic will be described in detail with reference to the drawings. Note that, the shapes and arrangements of the electrocaloric effect element and respective constituent elements according to the present embodiment are not limited to those in the illustrated examples.

### [Ceramic]

The ceramic according to an embodiment of the present disclosure contains Pb, Sc, Ta, Mg, and W as main components. The ceramic is a composite oxide containing Pb, Sc, Ta, Mg, and W.

A content of Pb is substantially equal to a total content of Sc, Ta, Mg, and W.

When a content of Sc is “0.5−x”, a content of Ta is “0.5+x”, and when a content of Mg is “0.5−y”, a content of W is “0.5+y”.

The ranges of x and y are set such that
x, y≤0.1 and 0≤x+y≤0.13 when 0 x, y,
−0.1≤x<0 and 0≤y≤0.1 when 0>x and 0≤y,
−0.1≤x, y and −0.13≤x+y<0 when 0≥x and 0>y, and

0<x≤0.1 and −0.1≤y<0 when 0<x and 0>y.

When a total content of Mg and W is denoted by “m”, a total content of Sc and Ta is “1−m”, and the range of m is 0.60≤m≤0.95. All of the above contents are molar ratios. When the composition in the above ranges is employed, a large electrocaloric effect can be obtained at a low electric field.

The expression “the content of Pb is substantially equal to the total content of Sc, Ta, Mg, and W” is not limited to a case where the content of Pb is exactly equal to the total content of Sc, Ta, Mg, and W. That is, the expression “the content of Pb is substantially equal to the total content of Sc, Ta, Mg, and W” includes a case where the difference between the content of Pb and the total content of Sc, Ta, Mg, and W is, for example, 3% or less in terms of molar ratio.

The composition of the ceramic of the present disclosure can be analyzed and measured by performing composition analysis using, for example, high-frequency inductively coupled plasma emission spectroscopy, or X-ray fluorescence spectroscopy.

The electrocaloric effect is an endothermic and exothermic phenomenon caused by a change in entropy when electric dipole moments in a substance are aligned or disordered by a change in the electric field. A performance indicator of the electrocaloric effect in the present disclosure may be an adiabatic temperature change (ΔT). That is, the expression “the electrocaloric effect is large” may mean that the adiabatic temperature change (ΔT) is large. In the present disclosure, a larger adiabatic temperature change (ΔT) is more preferable.

The adiabatic temperature change ΔT means a temperature change of the ceramic caused by application of the electric field to the ceramic and/or removal of the electric field applied to the ceramic. Specifically, the adiabatic temperature change ΔT may be a difference between a temperature of the ceramic before application of the electric field and a temperature of the ceramic immediately after application of the electric field, or may be a difference between a temperature of the ceramic before removal of the electric field and a temperature of the ceramic immediately after removal of the electric field.

In general, the adiabatic temperature change ΔT increases as the electric field intensity to be applied to the ceramic increases. The adiabatic temperature change ΔT tends to increase as the temperature of the ceramic at the time of application of the electric field approaches the antiferroelectric transition temperature (or ferroelectric transition temperature). For example, the electrocaloric effect rapidly decreases as the temperature of the ceramic becomes lower than the transition temperature. Specifically, in the conventional PMW having a transition temperature of about 20 to 30° C., the electrocaloric effect tends to decrease significantly when the temperature of the ceramic is 0° C. or lower.

In another aspect, the ceramic may be a ceramic represented by Formula (1):

(1−m)PbSc_{0.5-x}Ta_{0.5+x}O₃−mPbMg_{0.5-y}W_{0.5+y}O₃ (1)

wherein
0.60≤m≤0.95,
x, y≤0.1 and 0≤x+y≤0.13 when 0≤x, y,
−0.1≤x<0 and 0≤y≤0.1 when 0>x and 0≤y,
−0.1≤x, y and −0.13≤x+y<0 when 0≥x and 0>y, and
0<x≤0.1 and −0.1≤y<0 when 0<x and 0>y.

When x, y, and m are set within the above ranges, a large electrocaloric effect (for example, 0.8 K or more when an electric field intensity of 8 MV/m is applied) at a low electric field can be obtained.

Although the present disclosure is not bound by any theory, a mechanism for obtaining the above effect is considered as follows.

Examples of the substance exhibiting a large electrocaloric effect include PMW exhibiting antiferroelectricity and PbSc_{0.5}Ta_{0.5}O₃ (hereinafter, a ceramic containing Pb, Sc, and Ta is also referred to as “PST”) exhibiting ferroelectricity. The PMW and PST show antiferroelectricity and ferroelectricity, respectively, which have a large latent heat at the time of transition due to alignment of cations at the B site (Mg and W for PMW, Sc, and Ta for PST).

In the case of the PMW, the PMW exhibits a negative electrocaloric effect (heat absorption at the time of application of the electric field and heat generation at the time of removal of the electric field) derived from its antiferroelectricity at a temperature equal to or lower than the phase transition temperature, and exhibits a large positive electrocaloric effect (heat generation at the time of application of the electric field, and heat absorption at the time of removal of the electric field) in the vicinity of the transition temperature. That is, the positive and negative of the electrocaloric effect are inverted depending on the temperature. As the electrocaloric effect for practical use, both a positive electrocaloric effect and a negative electrocaloric effect may be used. In the case of the PMW, a large electric field intensity of 10 MV/m or more is required to obtain a large negative electrocaloric effect, and when the electric field intensity is less than 10 MV/m, the PMW exhibits only a very small electrocaloric effect.

In general, it is known that cations at the B site are easily aligned as the difference in ionic radius between two cations at the B site is larger. In the PMW, the difference in ionic radius between Mg and W is larger than that in the PST, so that ions at the B site is easily aligned. Accordingly, unlike the PST, the PMW has a feature that ions at the B site are aligned without performing a heat treatment for a long time. In the present disclosure, the threshold voltage of the antiferroelectric has been successfully lowered by adding the PST to the PMW. This is considered to be because the alignment of ions at the B site of the PMW is moderately decreased.

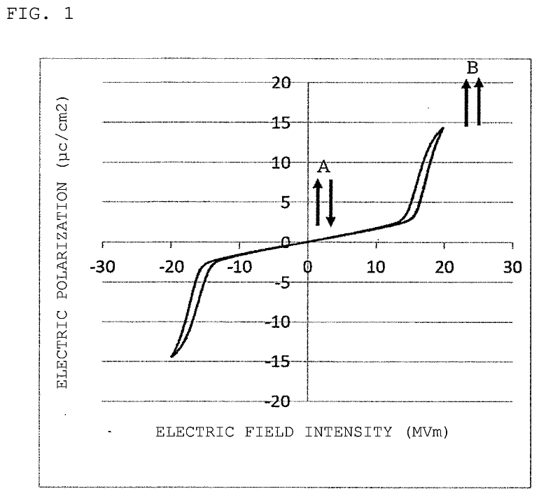

The threshold voltage means a voltage (about 18 MV/m) at which electric polarization rapidly increases as shown in FIG. 1. When the voltage is equal to or lower than the threshold voltage, the electric polarizations are arranged so as to cancel each other. When the voltage is equal to or higher than the threshold voltage, the electric polarizations start to be aligned in the electric field direction. In a stronger electric field, the polarizations are all aligned in one direction similarly to general ferroelectrics. That is, the antiferroelectric is induced to have electric polarization similar to that of the ferroelectric by applying a voltage equal to or higher than the threshold voltage to the antiferroelectric. When the voltage is equal to or lower than the threshold voltage, the antiferroelectric does not exhibit an electrocaloric effect because the electric polarizations are arranged so as to cancel each other (state A in FIG. 1). When the voltage exceeds the threshold voltage, the antiferroelectric exhibits a positive or negative electrocaloric effect depending on the magnitude of the voltage because the electric polarizations are aligned (state B in FIG. 1).

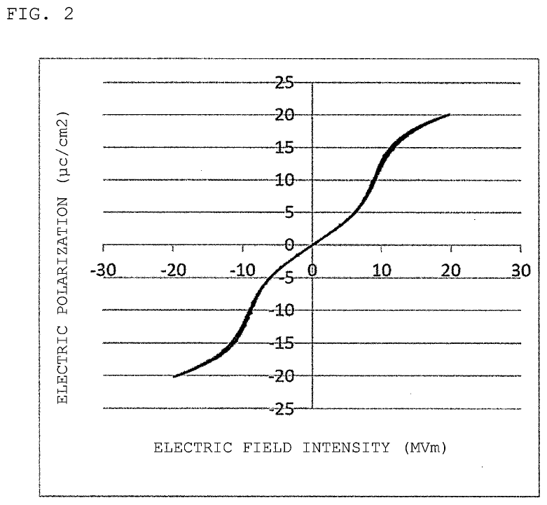

As shown in FIG. 2, in the ceramic according to the present disclosure, the threshold voltage decreases. As a result, the ceramic of the present disclosure can exhibit an electrocaloric effect at a low electric field. In the ferroelectric, when an electric field is applied once, a part of polarization remains (referred to as residual polarization), and entropy change at the time of application and removal of the electric field is reduced by the amount of the residual polarization, to cause loss of the electrocaloric effect. On the other hand, in the case of the antiferroelectric, the electric polarization returns to zero when the electric field is removed, and thus loss of the electrocaloric effect does not occur.

In the present disclosure, when the PST is added to the PMW, not only the threshold voltage of the antiferroelectric is lowered, but also the transition temperature of the PMW is successfully lowered to room temperature or lower. That is, as compared with the conventional PMW, the ceramic of the present disclosure can provide an excellent electrocaloric effect at 0° C. or lower (for example, −15° C.).

Further, in the present disclosure, it is also possible to prevent inversion of the positive and negative of the electrocaloric effect from occurring in the temperature range of actual use (for example,−20 to 0° C.), at a relatively low electric field intensity, and 8 MV/m or more. Therefore, as compared with the conventional PMW, the ceramic of the present disclosure has improved controllability of the electrocaloric effect, and does not require complicated control when used as a cooling system.

In one aspect, the ranges of x and y are set such that
x, y≤0.1 and 0≤x+y≤0.12 when 0≤x, y,
−0.1≤x<0 and 0≤y≤0.1 when 0>x and 0≤y,
−0.1≤x, y and −0.12≤x+y<0 when 0≥x and 0>y, and
0<x≤0.1 and −0.1≤y<0 when 0<x and 0>y.

In one aspect, the ranges of x and y are set such that
x, y≤0.1 and 0≤x+y≤0.11 when 0≤x, y,
−0.1≤x<0 and 0≤y≤0.1 when 0>x and 0≤y,
−0.1≤x, y and −0.11≤x+y<0 when 0≥ x and 0>y, and
0<x≤0.1 and −0.1≤y<0 when 0<x and 0>y.

In one aspect, the ranges of x and y are set such that
0≤x+y≤0.1 when 0≤x, y,
−0.1≤x<0 and 0≤y 0.1≤when 0>x and 0≤y,
−0.1≤x+y<0 when 0≥x and 0>y, and
0<x≤0.1 and −0.1≤y<0 when 0<x and 0>y.

In one aspect, the ranges of x and y are set such that
0≤x+y≤0.08 when 0≤x, y,
−0.08≤x<0 and 0≤y≤0.08 when 0>x and 0≤y,
−0.08≤x+y<0 when 0≥x and 0>y, and
0<x≤0.08 and −0.08≤y<0 when 0<x and 0>y.

In one aspect, the ranges of x and y are set such that
0≤x≤0.05 and 0≤y≤0.05 when 0≤x, y,
−0.05≤x<0 and 0≤y≤0.05 when 0>x and 0≤y,
−0.05≤x<0 and −0.05≤y<0 when 0≥x and 0>y, and
0<x≤0.05 and −0.05≤y<0 when 0<x and 0>y.

In another aspect, the ranges of x and y are set such that
0≤x+y≤0.05 when 0≤x, y,
−0.05≤x<0 and 0≤y≤0.05 when 0>x and 0≤y,
−0.05≤x+y<0 when 0≥x and 0>y, and
0<x≤0.05 and −0.05≤y<0 when 0<x and 0>y.

In one aspect, the ranges of x and y may be determined by optionally combining the ranges of x and y in the cases of “0≤x, y”, “0>x, 0≤y”, “0≥x, 0>y”, and “0<x, 0>y” described above.

In a preferred aspect, x and y are 0. That is, the formula represented by (1−m) PbSc_{0.5-x}Ta_{0.5+x}O₃−mPbMg_{0.5-y}W_{0.5+z}O₃ is (1−m) PbSc_{0.5}Ta_{0.5}O₃−mPbMg_{0.5}W_{0.5}O₃.

In one aspect, m may be 0.60<m 0.95.

The range of m is preferably 0.60 m 0.90, more preferably 0.70≤m≤0.90, and still more preferably 0.70≤m≤0.80 from the viewpoint of improving the electrocaloric effect at a low electric field.

The range of m is preferably 0.60≤m≤0.90, more preferably 0.65≤m≤0.90, and still more preferably 0.65≤m≤0.85 from the viewpoint of improving the electrocaloric effect at a low temperature.

The range of m may be 0.90≤m≤0.95 from the viewpoint of obtaining a negative electrocaloric effect.

The range of m may be 0.60≤m≤0.80 from the viewpoint of obtaining a positive electrocaloric effect.

The crystal structure of the ceramic according to an embodiment of the present disclosure may be a perovskite structure. The ceramic having a perovskite structure means not only a ceramic having a “perovskite crystal structure”, but also a ceramic having a “crystal structure similar to the perovskite crystal structure”. For example, the ceramic having a perovskite structure may have a crystal structure that can be recognized as the crystal structure of perovskite by those skilled in the art of ceramic in X-ray diffraction.

### [Electrocaloric Effect Element]

An electrocaloric effect element of the present disclosure has a laminate in which an electrode layer and a ceramic layer containing the ceramic of the present disclosure as a main component are alternately stacked.

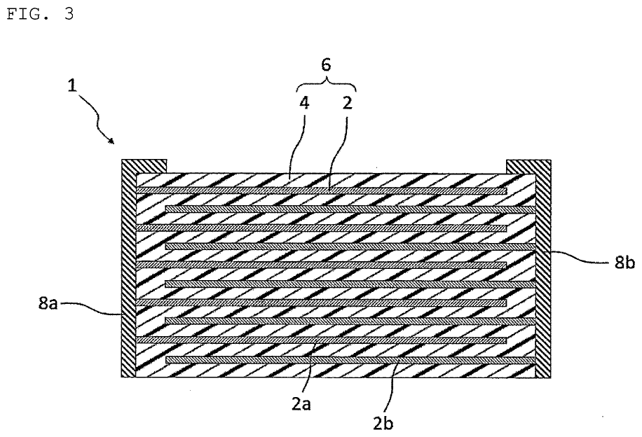

As shown in FIG. 3, an electrocaloric effect element 1 according to an embodiment of the present disclosure includes a laminate 6 in which electrode layers 2a and 2b (hereinafter, also collectively referred to as “electrode layer 2”) and a ceramic layer 4 are alternately stacked, and external electrodes 8a and 8b (hereinafter, also collectively referred to as “external electrode 8”) connected to the electrode layer 2. The electrode layers 2a and 2b are electrically connected to the external electrodes 8a and 8b arranged on an end surface of the laminate 6, respectively. When a voltage is applied from the external electrodes 8a and 8b, an electric field is formed between the electrode layers 2a and 2b. This electric field causes the ceramic layer 4 to generate heat due to the electrocaloric effect. When the voltage is removed, the electric field disappears, and as a result, the ceramic layer 4 absorbs heat due to the electrocaloric effect.

The electrode layer 2 is a so-called internal electrode. The electrode layer 2 can have a function of transferring a heat quantity between the ceramic layer 4 and the outside in addition to a function of applying the electric field to the ceramic layer 4.

The electrode layer 2 may be an electrode layer containing a noble metal as a main component. Here, the “main component” in the electrode layer 2 means that the electrode layer 2 is formed from 80 mass % or more of noble metal, and for example, means that 95 mass % or more, more preferably 98 mass % or more, further preferably 99 mass % or more, still more preferably 99.5 mass % or more, and particularly preferably 99.9 mass % or more of the electrode layer 2 is noble metal.

In the present specification, the “noble metal” may be, for example, Au, Ag, Pt, or Pd. From the viewpoint of improving the electrocaloric effect at a low temperature, the main component of the electrode layer 2 used in the present disclosure may be Pt or Pd. That is, the electrode layer 2 may be a Pt or Pd electrode layer. However, from the viewpoint of improving chemical durability and/or cost, the electrode layer 2 of the noble metal may be an alloy (for example, an Ag—Pd alloy, and the like) or a mixture of Pt and/or Pd and another element (for example, Ag, Pd, Rh, Au, and the like). When the Pt or Pd electrode layer is formed of an alloy or a mixture thereof, a similar effect can be obtained. Other elements that can be mixed as impurities, particularly inevitable elements (for example, Fe, Al₂O₃, and the like) may be contained. In this case, similar effects are achievable.

The thickness of the electrode layer 2 can be preferably 0.2 μm to 10 μm, more preferably 1.0 μm to 5.0 μm, for example, 2.0 μm to 5.0 μm, or 2.0 μm to 4.0 μm. When the thickness of the electrode layer 2 is 0.5 μm or more, resistance of the electrode layer 2 can be reduced, and heat transport efficiency can be increased. When the thickness of the electrode layer 2 is 10 μm or less, the thickness (thus, volume) of the ceramic layer can be increased, and the heat quantity that can be handled by the electrocaloric effect of the entire element can be further increased. In addition, the element can be made smaller.

The ceramic layer 4 may contain one type of ceramic as a main component, or two or more types of ceramics as main components.

Here, the “main component” in the ceramic layer means that the ceramic layer is substantially formed from a target ceramic, and for example, means that 90 mass % or more, more preferably 95 mass % or more, further preferably 98 mass % or more, still more preferably 99 mass % or more, and particularly preferably 99.5 mass % or more of the ceramic layer is the target ceramic. The other component may be a crystal phase having a structure different from the perovskite structure, which is a pyrochlore structure, other elements mixed as impurities, and particularly inevitable elements (for example, Zr, C, and the like).

The composition of the ceramic layer 4 can be determined by, for example, high-frequency inductively coupled plasma emission spectroscopy, X-ray fluorescence spectroscopy, or another method. The structure of the ceramic layer 4 can be determined by powder X-ray diffraction.

The thickness of the ceramic layer 4 can be preferably 5 μm to 100 μm, more preferably 5 μm to 50 μm, further preferably 10 μm to 50 μm, still more preferably 20 μm to 50 μm, and particularly preferably 20 μm to 40 μm. When the thickness of the ceramic layer 4 is further increased, the heat quantity that can be handled by the element can be increased. When the thickness of the ceramic layer 4 is further reduced, a higher ΔT can be obtained, and the withstand voltage can also be improved.

The withstand voltage of the ceramic layer 4 can be preferably 15 MV/m or more, more preferably 20 MV/m or more, and still more preferably 25 MV/m or more. When the withstand voltage of the ceramic layer 4 is further increased, a larger voltage (electric field) can be applied, and a larger ΔT can be obtained.

A material constituting a pair of the external electrodes 8a and 8b is not particularly limited, examples thereof include Ag, Cu, Pt, Ni, Al, Pd, Au, and alloys thereof (for example, Ag—Pd and the like), and an electrode composed of these metals and glass or an electrode composed of metal and resin may be used. Among the metals, Ag is preferable.

In the electrocaloric effect element 1, the electrode layer 2 and the ceramic layer 4 are alternately stacked. In the electrocaloric effect element of the present disclosure, the number of stacked electrode layers 2 and ceramic layers 4 is not particularly limited. All the internal electrodes may not be connected to the external electrodes, and may include internal electrodes that are not connected to the external electrodes as necessary for heat transfer, stress relaxation due to piezoelectricity and electrostriction, and the like.

In the electrocaloric effect element 1, the internal electrode and the ceramic layer are in contact with each other on substantially the entire surface. However, the electrocaloric effect element of the present disclosure is not limited to such a structure, and is not particularly limited as long as it has a structure capable of applying a voltage (electric field) to the ceramic layer. Although the electrocaloric effect element 1 has a rectangular parallelepiped block shape, the shape of the electrocaloric effect element of the present disclosure is not limited thereto. For example, the electrocaloric effect element 1 may have a cylindrical shape or a sheet shape, and may further have unevenness, a through hole, or the like. The internal electrode may be exposed on a surface for heat transfer or heat exchange with the outside.

The ceramic and electrocaloric effect element of the present embodiment described above is manufactured, for example, as follows.

As raw materials, high purity lead oxide (Pb₃O₄), tantalum oxide (Ta₂O₅), scandium oxide (Sc₂O₃), magnesium carbonate (MgCO₃), and tungsten oxide (WO₃) are weighed so as to have a desired composition ratio after firing. The above raw materials are pulverized and mixed with partially stabilized zirconia (PSZ) balls, pure water, a dispersant, and the like by a ball mill. Thereafter, a slurry obtained by pulverization and mixing is dried and sized, and then calcined under the conditions of, for example, 800° C. to 900° C. in an air atmosphere. A calcined powder obtained is mixed with PSZ balls, ethanol, toluene, a dispersant, and the like and pulverized. Next, a dissolved binder solution is added to the pulverized powder obtained, and mixed to prepare a slurry for sheet forming. The prepared slurry is formed into a sheet shape on a support, and a Pt electrode paste is applied thereon. A sheet to which the Pt electrode paste has been applied and a sheet to which the Pt electrode paste has not been applied are stacked so as to have a desired structure, and then the stack is pressure-bonded at a pressure of 100 MPa to 200 MPa, and cut to prepare a green chip. The green chip is heat-treated at 500° C. to 600° C. in an air atmosphere to perform a binder removal treatment. Next, the chip subjected to binder removal is fired at 800° C. to 1,400° C. together with a PbZrO₃ powder for creating a Pb atmosphere using, for example, an alumina sealed sagger. Thereafter, the end surfaces of the chip are polished with sandpaper, an external electrode paste is applied, and baking treatment is performed at a predetermined temperature, so that an electrocaloric effect element as shown in FIG. 3 can be obtained.

The electrocaloric effect element of the present disclosure exhibits an excellent electrocaloric effect, and thus can be used as a heat management element, particularly as a cooling element (including cooling/heat pump elements of an air conditioning apparatus such as an air conditioner, a refrigerator, and a freezer).

The present disclosure also provides an electronic component including the electrocaloric effect element of the present disclosure, and an electronic device including the electrocaloric effect element of the present disclosure or the electronic component.

The electronic component is not particularly limited, and examples thereof include electronic components used for an air conditioner, a refrigerator or a freezer, or electronic components (for example, batteries) used for an air conditioner of electric vehicles and hybrid cars; and components commonly used for electronic devices such as integrated circuits (ICs) such as a central processing unit (CPU), a hard disk (HDD), a power management IC (PMIC), a power amplifier (PA), a transceiver IC, and a voltage regulator (VR); light-emitting elements such as a light emitting diode (LED), an incandescent light bulb, and a semiconductor laser; components which can be a heat sources such as a field-effect transistors (FET); and other components, for example, a lithium ion battery, a substrate, a heat sink, a housing, and the like.

The electronic device is not particularly limited, and examples thereof include an air conditioner, a refrigerator, and a freezer; an air conditioner used as a heat pump, an air conditioner of electric vehicles or hybrid cars, and small electronic devices such as a cellular phone, a smartphone, a personal computer (PC), a tablet terminal, a hard disk drive, and a data server.

The electrocaloric effect element of the present disclosure can be used as a heat management system (or a temperature management system) that manages heat (temperature) of the electronic component and the electronic device. Examples of the heat management system include a cooling system that cools the electronic component and the electronic device.

### EXAMPLES

### <Production of Electrocaloric Effect Element>

As raw materials, high purity lead oxide (Pb₃O₄), tantalum oxide (Ta₂O₅), scandium oxide (Sc₂O₃), magnesium carbonate (MgCO₃), and tungsten oxide (WO₃) were prepared. These raw materials were weighed so as to have a predetermined composition ratio as shown in Tables 1 to 4 after firing, and pulverized and mixed with partially stabilized zirconia (PSZ) balls having a diameter of 2 mm, pure water, and a dispersant by a ball mill for 16 hours. Thereafter, a slurry obtained by pulverization and mixing was dried on a hot plate and sized, and then calcined for 2 hours under the condition of 850° C. in an air atmosphere.

A calcined powder obtained was mixed with PSZ balls having a diameter of 5 mm, ethanol, toluene, and a dispersant for 16 hours, and pulverized. Next, a dissolved binder solution was added to a pulverized powder obtained, and mixed for 4 hours to prepare a slurry for sheet forming. The prepared slurry was formed into a sheet shape on a PET film by a doctor blade method in a thickness corresponding to a thickness of a predetermined ceramic layer, cut into strips, and then a platinum internal electrode paste was applied to the cut strips by screen printing. The thickness of a sheet of the stacked element to be produced was controlled by changing a gap of a doctor blade used at the time of sheet formation.

A predetermined number of sheets to which the platinum internal electrode paste had been applied and sheets to which the platinum internal electrode paste had not been applied were stacked, and then the stack was pressure-bonded at a pressure of 150 MPa, and cut to prepare a green chip. The green chip was heat-treated at 550° C. for 24 hours in an air atmosphere to perform the binder removal treatment. Next, the green chip was sealed in an alumina sealed sagger together with a PbZrO₃ powder for creating a Pb atmosphere, and fired at 900 to 1,300° C. for 4 hours. Samples within the scope of the present disclosure were sufficiently fired at a temperature of 900 to 1,250° C. A sample of sample No. 1 as Comparative Example shown in Table 1 was fired at a high temperature of 1,400° C. and then heat-treated at 1,000° C. for 1,000 hours.

Thereafter, the end surfaces of the chip were polished with sandpaper, an Ag external electrode paste was applied, and baking treatment was performed at a temperature of 750° C., so that an electrocaloric effect element as shown in FIG. 3 was obtained.

The size of the obtained element was about L 10.2 mm×W 7.2 mm×T 0.88 mm for the element in which the thickness of the ceramic layer was 40 μm. The number of ceramic layers sandwiched between the internal electrode layers was 19, the electrode area was 49 mm²/layer, and the total electrode area was 49 mm²×19 layers. The thickness of the ceramic layer of the element obtained above was confirmed using a scanning electron microscope after polishing a section of the element.

### <Evaluation>

### (Composition)

The ceramic composition of the obtained element was confirmed using high-frequency inductively coupled plasma emission spectroscopy and X-ray fluorescence spectroscopy.

### (Crystal Structure)

In order to evaluate the crystal structure of the obtained element, powder X-ray diffraction measurement was performed. One element was randomly selected from each lot and ground in a mortar, and then an X-ray diffraction profile was obtained. From the obtained X-ray diffraction profile, it was confirmed whether the crystal structure of the ceramic was the perovskite structure, and the presence or absence and abundance of an impurity phase (mainly a pyrochlore phase) were estimated from the intensity ratio. When the abundance of the perovskite structure was 0.95 or more, it was determined that the main component had the perovskite structure, and when the abundance was less than 0.95, it was determined that there was a heterophase.

### (Electrocaloric Effect)

An ultrafine K thermocouple having a diameter of 50 μm was attached to a central portion of the surface of an element with a Kapton tape. The temperature was constantly monitored, a wire for voltage application was bonded to both ends of the external electrode with an Ag paste, and a voltage was applied to the element using a high voltage generator.

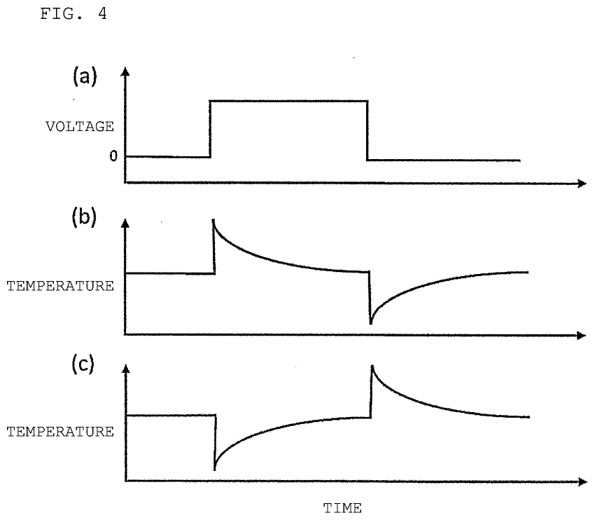

The electrocaloric effect was evaluated by applying a voltage to the sample in a sequence as shown in the graph of FIG. 4(a). That is, first, a voltage was applied to the sample, the voltage was held as it was, then the applied voltage was removed, and the sample was held in this state, and this operation was repeated to measure a change in the electrocaloric effect. When a voltage is applied to a ferroelectric in such a sequence, in the step of applying a voltage, the sample temperature rises simultaneously with the application of voltage, in the step of holding the applied state, heat is gradually diffused and the sample temperature drops to the same temperature as that before the application of voltage, in the step of removing the applied voltage, the sample temperature drops simultaneously with the removal of voltage, and in the step of holding the non-applied state, the sample temperature gradually rises to the original temperature (see FIG. 4(b)). This is because the ferroelectric domains are aligned or disturbed by application and removal of voltage, and such an endothermic and exothermic effect (electrocaloric effect) is obtained by change in entropy.

On the other hand, when a voltage is applied to an antiferroelectric in a sequence as shown in the graph of FIG. 4(a), the antiferroelectric shows an electrocaloric effect opposite to that of the ferroelectric in a specific temperature range, as shown in FIG. 4(c). That is, the antiferroelectric shows a negative caloric effect in which the temperature decreases (heat absorption) when the voltage is applied and increases (heat generation) when the voltage is removed.

In this example, for the adiabatic temperature change ΔT, after applying a predetermined voltage, the temperature was measured with the voltage kept applied for 50 seconds, and then after removing the voltage, the temperature was measured without any voltage applied for 50 seconds. This sequence was repeated three times. During the sequence of voltage application and voltage removal, the temperature of the element was constantly measured, and the adiabatic temperature change ΔT was obtained from the temperature change. Samples in which the absolute value of the adiabatic temperature change ΔT when electric fields of 8 MV/m and 15 MV/m were applied at −15° C. were 0.8 K to 1.5 K or more, respectively, were rated as “Go”. The results are shown in Tables 1 to 4.

Hereinafter, the above evaluation results are shown. Samples marked with “*” in the tables are Comparative Examples, and other samples are Examples.

TABLE 1

| | | | | | Absolute value | | | |
|---|---|---|---|---|---|---|---|---|
| | | | | | of adiabatic | | Sign of caloric effect | |
| | | | | | temperature change | | at −20° C. to 0° C. | |
| Sample | | (1 − m)PbSc_{0.5-x}Ta_{0.5+x}O3—mPbMg_{0.5-y}W_{0.5+y}O₃ | | | ΔT (K) | | and presence or absence | Crystal |
| No. | | m | x | y | 8 MV/m | 15 MV/m | of sign inversion | structure |
| * | 1 | 1 | 0 | 0 | 0.1 | 0.15 | Negative, no | Perovskite |
| | | | | | | | inversion | structure |
| * | 2 | 0 | 0 | 0 | 0.9 | 0.3 | Positive, no | Perovskite |
| | | | | | | | inversion | structure |
| * | 3 | 0.55 | 0 | 0 | 0.5 | 1.2 | Positive, no | Perovskite |
| | | | | | | | inversion | structure |
| | 4 | 0.6 | 0 | 0 | 1 | 2 | Positive, no | Perovskite |
| | | | | | | | inversion | structure |
| | 5 | 0.7 | 0 | 0 | 1.3 | 2.5 | Positive, no | Perovskite |
| | | | | | | | inversion | structure |
| | 6 | 0.8 | 0 | 0 | 1.5 | 2.7 | Positive, no | Perovskite |
| | | | | | | | inversion | structure |
| | 7 | 0.9 | 0 | 0 | 1 | 2.2 | Negative, no | Perovskite |
| | | | | | | | inversion | structure |
| | 8 | 0.95 | 0 | 0 | 0.8 | 1.5 | Negative, no | Perovskite |
| | | | | | | | inversion | structure |
| * | 9 | 0.97 | 0 | 0 | 0.1 | 0.2 | Negative, | Perovskite |
| | | | | | | | inversion | structure |

TABLE 2

| | | | | | Absolute value of | | |
|---|---|---|---|---|---|---|---|
| | | | | | adiabatic temperature | | |
| Sample | | (1 − m)PbSc_{0.5-x}Ta_{0.5+x}O3—mPbMg_{0.5-y}W_{0.5+y}O₃ | | | change ΔT (K) | | |
| No. | | m | x | y | 8 MV/m | 15 MV/m | Crystal structure |
| | 10 | 0.6 | 0 | 0 | 1 | 2 | Perovskite structure |
| | 11 | 0.6 | 0.05 | 0.05 | 1 | 1.8 | Perovskite structure |
| * | 12 | 0.6 | 0.08 | 0.08 | — | — | Many heterophases |
| * | 13 | 0.6 | 0.1 | 0.1 | 0.5 | 1.4 | Perovskite structure |
| | 14 | 0.6 | 0.05 | −0.05 | 1 | 2 | Perovskite structure |
| | 15 | 0.6 | 0.08 | −0.08 | 1.1 | 1.9 | Perovskite structure |
| | 16 | 0.6 | 0.1 | −0.1 | 1.1 | 2.1 | Perovskite structure |
| * | 17 | 0.6 | 0.1 | −0.11 | — | — | Many heterophases |
| * | 18 | 0.6 | 0.11 | −0.1 | — | — | Many heterophases |
| | 19 | 0.6 | −0.05 | −0.05 | 1 | 1.7 | Perovskite structure |
| * | 20 | 0.6 | −0.08 | −0.08 | — | — | Many heterophases |
| * | 21 | 0.6 | −0.1 | −0.1 | — | — | Many heterophases |
| | 22 | 0.6 | −0.05 | 0.05 | 1 | 1.8 | Perovskite structure |
| | 23 | 0.6 | −0.08 | 0.08 | 1 | 1.7 | Perovskite structure |
| | 24 | 0.6 | −0.1 | 0.1 | 1 | 1.6 | Perovskite structure |
| * | 25 | 0.6 | −0.1 | 0.11 | — | — | Many heterophases |
| * | 26 | 0.6 | −0.11 | 0.1 | — | — | Many heterophases |
| | 27 | 0.6 | 0 | 0.05 | 1.1 | 1.7 | Perovskite structure |
| | 28 | 0.6 | 0 | 0.08 | 1 | 1.8 | Perovskite structure |
| | 29 | 0.6 | 0 | 0.1 | 1.1 | 1.7 | Perovskite structure |
| * | 30 | 0.6 | 0 | 0.11 | — | — | Many heterophases |
| | 31 | 0.6 | 0.05 | 0 | 1 | 1.7 | Perovskite structure |
| | 32 | 0.6 | 0.08 | 0 | 1 | 1.8 | Perovskite structure |
| | 33 | 0.6 | 0.1 | 0 | 1 | 1.9 | Perovskite structure |
| * | 34 | 0.6 | 0.11 | 0 | — | — | Many heterophases |
| | 35 | 0.6 | 0 | −0.05 | 1 | 1.9 | Perovskite structure |
| | 36 | 0.6 | 0 | −0.08 | 1.1 | 2.1 | Perovskite structure |
| | 37 | 0.6 | 0 | −0.1 | 1 | 2 | Perovskite structure |
| * | 38 | 0.6 | 0 | −0.11 | — | — | Many heterophases |
| | 39 | 0.6 | −0.05 | 0 | 1 | 1.9 | Perovskite structure |
| | 40 | 0.6 | −0.08 | 0 | 1 | 1.8 | Perovskite structure |
| | 41 | 0.6 | −0.1 | 0 | 1 | 2 | Perovskite structure |
| * | 42 | 0.6 | −0.11 | 0 | — | — | Many heterophases |

TABLE 3

| | | | | | Absolute value of | | |
|---|---|---|---|---|---|---|---|
| | | | | | adiabatic temperature | | |
| Sample | | (1 − m)PbSc_{0.5-x}Ta_{0.5+x}O3—mPbMg_{0.5-y}W_{0.5+y}O₃ | | | change ΔT (K) | | |
| No. | | m | x | y | 8 MV/m | 15 MV/m | Crystal structure |
| | 43 | 0.8 | 0 | 0 | 1.5 | 2.7 | Perovskite structure |
| | 44 | 0.8 | 0.05 | 0.05 | 1.3 | 2.5 | Perovskite structure |
| * | 45 | 0.8 | 0.08 | 0.08 | — | — | Many heterophases |
| * | 46 | 0.8 | 0.1 | 0.1 | 0.6 | 1.4 | Perovskite structure |
| | 47 | 0.8 | 0.05 | −0.05 | 1.1 | 2.3 | Perovskite structure |
| | 48 | 0.8 | 0.08 | −0.08 | 1.2 | 2.5 | Perovskite structure |
| | 49 | 0.8 | 0.1 | −0.1 | 1.2 | 2.6 | Perovskite structure |
| * | 50 | 0.8 | 0.1 | −0.11 | — | — | Many heterophases |
| * | 51 | 0.8 | 0.11 | −0.1 | — | — | Many heterophases |
| | 52 | 0.8 | −0.05 | −0.05 | 1.1 | 2.6 | Perovskite structure |
| * | 53 | 0.8 | −0.08 | −0.08 | — | — | Many heterophases |
| * | 54 | 0.8 | −0.1 | −0.1 | — | — | Many heterophases |
| | 55 | 0.8 | −0.05 | 0.05 | 1 | 2.2 | Perovskite structure |
| | 56 | 0.8 | −0.08 | 0.08 | 1.5 | 2.4 | Perovskite structure |
| | 57 | 0.8 | −0.1 | 0.1 | 1.4 | 2.6 | Perovskite structure |
| * | 58 | 0.8 | −0.1 | 0.11 | — | — | Many heterophases |
| * | 59 | 0.8 | −0.11 | 0.1 | — | — | Many heterophases |
| | 60 | 0.8 | 0 | 0.05 | 1.2 | 2.5 | Perovskite structure |
| | 61 | 0.8 | 0 | 0.08 | 1.5 | 2.9 | Perovskite structure |
| | 62 | 0.8 | 0 | 0.1 | 1.4 | 2.7 | Perovskite structure |
| * | 63 | 0.8 | 0 | 0.11 | — | — | Many heterophases |
| | 64 | 0.8 | 0.05 | 0 | 1.6 | 2.6 | Perovskite structure |
| | 65 | 0.8 | 0.08 | 0 | 1.5 | 2.6 | Perovskite structure |
| | 66 | 0.8 | 0.1 | 0 | 1.7 | 2.8 | Perovskite structure |
| * | 67 | 0.8 | 0.11 | 0 | — | — | Many heterophases |
| | 68 | 0.8 | 0 | −0.05 | 1.5 | 2.7 | Perovskite structure |
| | 69 | 0.8 | 0 | −0.08 | 1.6 | 2.6 | Perovskite structure |
| | 70 | 0.8 | 0 | −0.1 | 1.7 | 2.6 | Perovskite structure |
| * | 71 | 0.8 | 0 | −0.11 | — | — | Many heterophases |
| | 72 | 0.8 | −0.05 | 0 | 1.5 | 2.6 | Perovskite structure |
| | 73 | 0.8 | −0.08 | 0 | 1.4 | 2.5 | Perovskite structure |
| | 74 | 0.8 | −0.1 | 0 | 1.3 | 2.4 | Perovskite structure |
| * | 75 | 0.8 | −0.11 | 0 | — | — | Many heterophases |

TABLE 4

| | | | | | Absolute value of | | |
|---|---|---|---|---|---|---|---|
| | | | | | adiabatic temperature | | |
| Sample | | (1 − m)PbSc_{0.5-x}Ta_{0.5+x}O3—mPbMg_{0.5-y}W_{0.5+y}O₃ | | | change ΔT (K) | | |
| No. | | m | x | y | 8 MV/m | 15 MV/m | Crystal structure |
| | 76 | 0.95 | 0 | 0 | 0.8 | 1.5 | Perovskite structure |
| | 77 | 0.95 | 0.05 | 0.05 | 1.5 | 1.6 | Perovskite structure |
| * | 78 | 0.95 | 0.08 | 0.08 | — | — | Many heterophases |
| * | 79 | 0.95 | 0.1 | 0.1 | 0.3 | Element | Many heterophases |
| | | | | | | breakdown | |
| | | | | | | occurred | |
| | 80 | 0.95 | 0.05 | −0.05 | 1.4 | 1.9 | Perovskite structure |
| | 81 | 0.95 | 0.08 | −0.08 | 1 | 1.7 | Perovskite structure |
| | 82 | 0.95 | 0.1 | −0.1 | 0.8 | 1.6 | Perovskite structure |
| * | 83 | 0.95 | 0.1 | −0.11 | — | — | Many heterophases |
| * | 84 | 0.95 | 0.11 | −0.1 | — | — | Many heterophases |
| | 85 | 0.95 | −0.05 | −0.05 | 0.9 | 1.6 | Perovskite structure |
| * | 86 | 0.95 | −0.08 | −0.08 | — | — | Many heterophases |
| * | 87 | 0.95 | −0.1 | −0.1 | — | — | Many heterophases |
| | 88 | 0.95 | −0.05 | 0.05 | 1 | 1.7 | Perovskite structure |
| | 89 | 0.95 | −0.08 | 0.08 | 0.9 | 1.8 | Perovskite structure |
| | 90 | 0.95 | −0.1 | 0.1 | 1 | 1.7 | Perovskite structure |
| * | 91 | 0.95 | −0.1 | 0.11 | — | — | Many heterophases |
| * | 92 | 0.95 | −0.11 | 0.1 | — | — | Many heterophases |
| | 93 | 0.95 | 0 | 0.05 | 1.1 | 1.9 | Perovskite structure |
| | 94 | 0.95 | 0 | 0.08 | 0.9 | 1.8 | Perovskite structure |
| | 95 | 0.95 | 0 | 0.1 | 0.9 | 1.6 | Perovskite structure |
| * | 96 | 0.95 | 0 | 0.11 | — | — | Many heterophases |
| | 97 | 0.95 | 0.05 | 0 | 0.8 | 1.6 | Perovskite structure |
| | 98 | 0.95 | 0.08 | 0 | 0.9 | 1.6 | Perovskite structure |
| | 99 | 0.95 | 0.1 | 0 | 0.8 | 1.5 | Perovskite structure |
| * | 100 | 0.95 | 0.11 | 0 | — | — | Many heterophases |
| | 101 | 0.95 | 0 | −0.05 | 0.8 | 1.5 | Perovskite structure |
| | 102 | 0.95 | 0 | −0.08 | 0.9 | 1.6 | Perovskite structure |
| | 103 | 0.95 | 0 | −0.1 | 0.9 | 1.6 | Perovskite structure |
| * | 104 | 0.95 | 0 | −0.11 | — | — | Many heterophases |
| | 105 | 0.95 | −0.05 | 0 | 0.9 | 1.6 | Perovskite structure |
| | 106 | 0.95 | −0.08 | 0 | 0.8 | 1.5 | Perovskite structure |
| | 107 | 0.95 | −0.1 | 0 | 0.9 | 1.5 | Perovskite structure |
| * | 108 | 0.95 | −0.11 | 0 | — | — | Many heterophases |

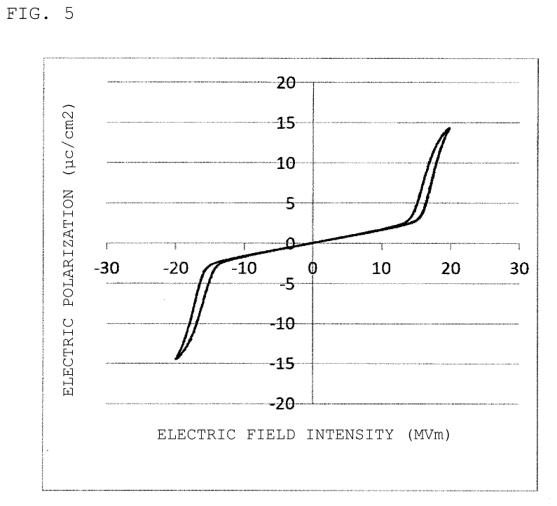

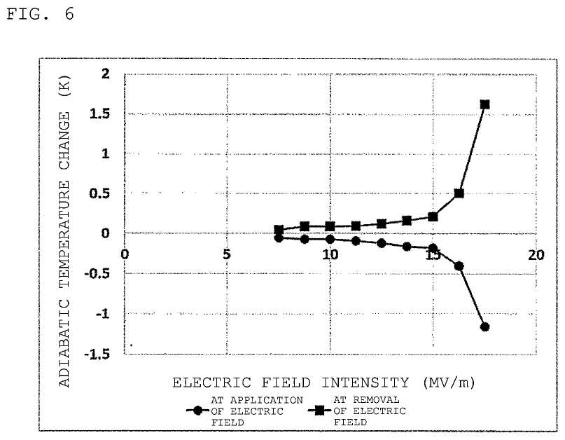

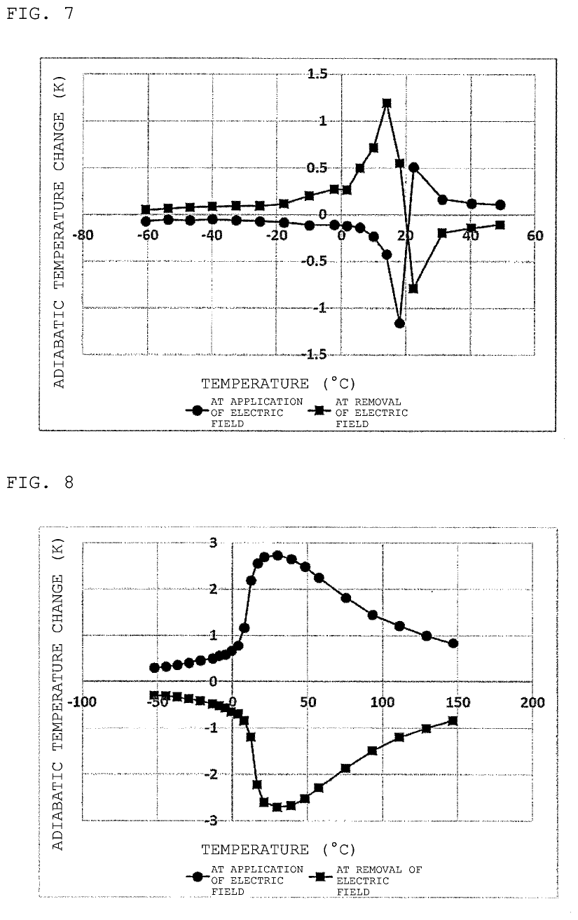

The ferroelectric characteristics of the conventional PMW shown in sample No. 1 are shown in FIG. 5, and the electrocaloric effect thereof is shown in FIGS. 6 and 7. As shown in FIG. 5, the conventional PMW exhibits double hysteresis characteristic of an antiferroelectric in which electric polarization rapidly increases from the threshold voltage (about 15 M4V/m) as the electric field intensity increases, and the electric polarization is saturated at a higher electric field intensity. The threshold voltage is about 15 MV/m at 15° C., but the threshold voltage increases as the temperature decreases, and a larger electric field is required.

FIG. 6 shows an adiabatic temperature change ΔT measured while changing the electric field intensity at 15° C. FIG. 7 shows an adiabatic temperature change ΔT measured while fixing the electric field intensity at 20 MV/m and changing the temperature. As shown in FIG. 6, in the measurement at 15° C., a negative caloric effect was obtained in which heat was absorbed when an electric field was applied and heat was generated when an electric field was removed. However, focusing on the relationship between the adiabatic temperature change ΔT and the electric field intensity, it was confirmed that almost no electrocaloric effect is exhibited at a low electric field, and the adiabatic temperature change ΔT gradually increases from the vicinity of the threshold voltage. That is, it was confirmed that a negative caloric effect was obtained in the PMW, but a sufficient electrocaloric effect was not obtained unless a large electric field of 12 MV/m or more was applied. Therefore, with the PMW, not only high electric field intensity is required, but also it is difficult to control the caloric effect by changing the electric field intensity.

As shown in FIG. 7, focusing on the temperature dependency of the adiabatic temperature change ΔT, it was confirmed that the caloric effect obtained at an electric field intensity of 20 MV/m at a temperature of 0° C. or lower was very small. Since the transition temperature of the PMW was in the vicinity of 20° C., the sign of the adiabatic temperature change ΔT changed at 20° C. near the transition temperature, and at 20° C. or higher, a positive caloric effect was obtained in which heat was generated when a voltage was applied and heat was absorbed when a voltage was removed. As described above, in the case of the antiferroelectric, the sign of the caloric effect is inverted in the temperature range exceeding the transition temperature, and thus it is very difficult to control the caloric effect. Therefore, simply lowering the transition temperature of the antiferroelectric may cause a problem that the sign of the caloric effect is inverted in a temperature range assumed to be used.

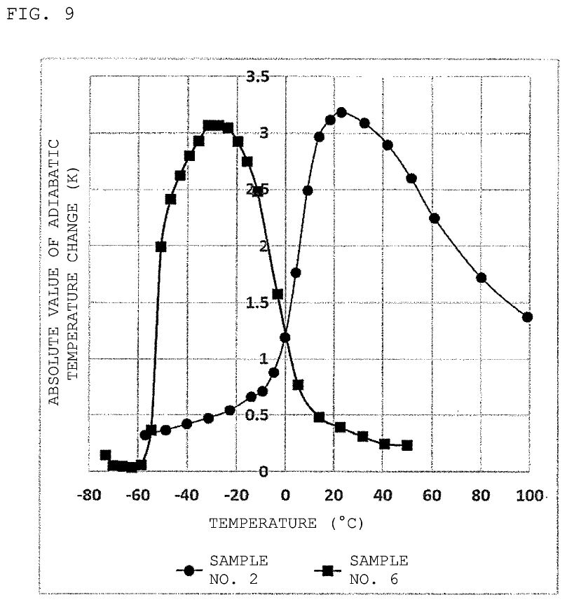

FIG. 8 shows an electrocaloric effect of the PST shown in the conventionally known sample No. 2. Unlike the PMW, in the PST, a positive caloric effect was obtained in all temperature ranges, the adiabatic temperature change ΔT was maximized in the vicinity of 20° C. of the transition temperature, and a very excellent caloric effect was obtained. However, the effect was rapidly reduced at 0° C. or lower, and a sufficient effect was not obtained at a low temperature.

Table 1 shows the characteristic test results of the samples prepared above. Specifically, Table 1 shows the electrocaloric effects of samples in which the values of x and y in Formula (1) are fixed to 0 and m is changed to various values. As a result of XRD measurement, in all the samples having the compositions shown in Table 1, the main component had a desired perovskite structure, and the number of heterophases was small.

The PMW shown in the conventionally known sample No. 1 and the PST shown in sample No. 2 had a low electrocaloric effect at −15° C., and the adiabatic temperature change was smaller than 1.5 K. On the other hand, in the samples having the compositions within the scope of the present disclosure, the absolute values of the adiabatic temperature change when electric fields of 8 MV/m and 15 MV/m were applied were 0.8 K and 1.5 K or more, respectively.

Samples in which m was in the range of 0.6 m 0.8 exhibited a positive caloric effect in the range of −20° C. to 0° C. when an electric field intensity of 15 MV/m was applied, and there was no inversion of the sign in this temperature range. Samples in which m was in the range of 0.8<m 0.95 exhibited a negative caloric effect in the above-described temperature range and electric field intensity, but there was no inversion of the sign.

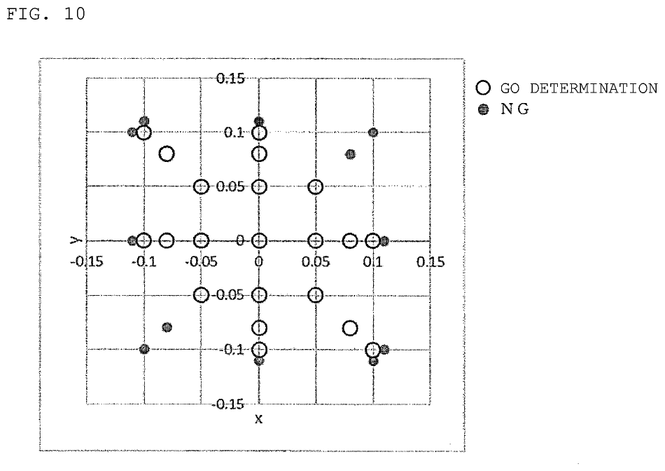

FIG. 9 shows the temperature dependency of the adiabatic temperature change when an electric field of 15 MV/m is applied for sample No. 2 and sample No. 6. (It is noted that, as shown in FIG. 7, the adiabatic temperature change of the sample of sample No. 1 was measured with a higher electric field intensity (20 MV/m), and as a result, the electrocaloric effect was small in the temperature range of 0° C. or lower, and thus the comparison here was omitted.)

As shown in FIG. 9, in the sample of sample No. 6 within the scope of the present disclosure, an excellent adiabatic temperature change was obtained in a wide temperature range from 0° C. to −50° C., which is equal to or lower than room temperature. Therefore, it can be seen that the ceramic of the present disclosure is suitable for applications requiring driving at a low temperature, such as a refrigerator and a freezer.

It is considered that when the value of m was less than 0.6, the ferroelectric transition temperature was not sufficiently lowered, and when the value of m was more than 0.95, not only the transition temperature was not sufficiently lowered, but also the threshold voltage of antiferroelectric was not lowered, so that the adiabatic temperature change at a low temperature and a low electric field was reduced.

Tables 2, 3, and 4 show the measurement results of the electrocaloric effects of the ceramics represented by Formula (1) in the cases where m is 0.6, m is 0.8, and m is 0.95, respectively.

Among the samples in which m is within the scope of the present disclosure, the proportion of the substance having a desired crystal structure was most stably close to 100% in the samples where both x and y are near 0. Even when both x and y are not in the vicinity of 0, no heterophase was generated, but when x and y are greatly deviated from 0, the proportion of the heterophase increased or the insulation property decreased, and element breakdown occurred when an electric field was applied (see the columns of crystal structure in Tables 2 to 4). However, in the compositions within the scope of the present disclosure, the main component had a desired structure, and the absolute values of the adiabatic temperature change when electric fields of 8 MV/m and 15 MV/m were applied at −15° C. were 0.8 K and 1.5 K or more, respectively.

FIG. 10 shows the composition ranges of x and y, which were rated as “Go” in the results of the characteristic test in Table 2. As shown in FIG. 10, it was confirmed that the ceramics within the scope of the present disclosure were rated as “Go” in the characteristic test. Tables 3 and 4 also show results similar to those in FIG. 10.

The electrocaloric effect element of the present disclosure can exhibit a high electrocaloric effect, and thus can be used as heat management elements in, for example, an electric vehicle or a hybrid car, an air conditioner (for example, an air conditioner used for an electric vehicle or a hybrid car, an air conditioner used as a heat pump, and the like), a refrigerator, a freezer, and the like. The electrocaloric effect element of the present disclosure can also be used as cooling devices of various electronic devices, for example, small electronic devices such as a cellular phone, a smartphone, a tablet terminal, a hard disk drive, a data server, and the like in which a heat countermeasure problem is remarkable, or a personal computer (PC) and the like.

### DESCRIPTION OF REFERENCE SYMBOLS

1: Electrocaloric effect element
2a, 2b: Electrode layer
4: Ceramic layer
6: Laminate
8a, 8b: External electrode

1. A ceramic represented by:
(1−m)PbSc_{0.5-x}Ta_{0.5+x}O₃−mPbMg_{0.5-y}W_{0.5+y}O₃
wherein
0.60≤m≤0.95,
when 0≤x, y, x, y≤0.1 and 0≤x+y≤0.13 when 0≤x, y,
−0.1≤x<0 and 0≤y≤0.1 when 0>x and 0≤y,
−0.1≤x, y and −0.13≤x+y<0 when 0≥x and 0>y, and
0<x≤0.1 and −0.1≤y<0 when 0<x and 0>y.

2. The ceramic according to claim 1, wherein
when 0≤x, y, 0≤x+y≤0.1 when 0≤x, y, and
−0.1≤x+y<0 when 0≤x and 0>y.

3. The ceramic according to claim 2, wherein x is 0 and y is 0.

4. The ceramic according to claim 1, wherein x is 0 and y is 0.

5. The ceramic according to claim 1, wherein 0.6≤m≤0.9.

6. The ceramic according to claim 1, wherein
x, y≤0.1 and 0≤x+y≤0.12 when 0≤x, y,
−0.1≤x<0 and 0≤y≤0.1 when 0>x and 0≤y,
−0.1≤x, y and −0.12≤x+y<0 when 0≥x and 0>y, and
0<x≤0.1 and −0.1≤y<0 when 0<x and 0>y.

7. The ceramic according to claim 1, wherein
x, y≤0.1 and 0≤x+y≤0.11 when 0≤x, y,
−0.1≤x<0 and 0≤y≤0.1 when 0>x and 0≤y,
−0.1≤x, y and −0.11≤x+y<0 when 0≥x and 0>y, and
0<x≤0.1 and −0.1≤y<0 when 0<x and 0>y.

8. The ceramic according to claim 1, wherein
0≤x+y≤0.1 when 0≤x, y,
−0.1≤x<0 and 0≤y≤0.1 when 0>x and 0≤y,
−0.1≤x+y<0 when 0≤x and 0>y, and
0<x≤0.1 and −0.1≤y<0 when 0<x and 0>y.

9. The ceramic according to claim 1, wherein
0≤x+y≤0.08 when 0≤x, y,
−0.08≤x<0 and 0≤y≤0.08 when 0>x and 0≤y,
−0.08≤x+y<0 when 0≤x and 0>y, and
0<x≤0.08 and −0.08≤y<0 when 0<x and 0>y.

10. The ceramic according to claim 1, wherein
0≤x≤0.05 and 0≤y≤0.05 when 0≤x, y,
−0.05≤x<0 and 0≤y≤0.05 when 0>x and 0≤y,
−0.05≤x<0 and −0.05≤y<0 when 0≥x and 0>y, and
0<x≤0.05 and −0.05≤y<0 when 0<x and 0>y.

11. The ceramic according to claim 1, wherein
0≤x+y≤0.05 when 0≤x, y,
−0.05≤x<0 and 0≤y≤0.05 when 0>x and 0≤y,
−0.05≤x+y<0 when 0>x and 0>y, and
0<x≤0.05 and −0.05≤y<0 when 0<x and 0>y.

12. The ceramic according to claim 1, wherein a crystal structure of the ceramic has a perovskite structure.

13. An electrocaloric effect element, wherein a noble metal electrode and the ceramic according to claim 1 are alternately stacked.

14. The electrocaloric effect element according to claim 13, wherein the noble metal electrode comprises Pt.

15. An electronic component comprising the electrocaloric effect element according to claim 13.

16. An electronic device comprising the electrocaloric effect element according to claim 13.

17. An electronic device comprising the electronic component according to claim 15.
